(19) United States
(12) Patent Application Publication
(10) Pub. No.: US 2011/0018053 A1
(43) Pub. Date: Jan. 27, 2011

(54) MEMORY CELL AND METHODS OF MANUFACTURING THEREOF

(75) Inventors: Guo Qiang Patrick Lo, Singapore Science Park 2 (SG); Jia Fu, Singapore Science Park 2 (SG); Mingbin Yu, Singapore Science Park 2 (SG); Navab Singh, Singapore Science Park 2 (SG)

Correspondence Address: Altera Law Group, LLC, 220 S 6 St Suite 1700, Minneapolis, MN, 55402, US

(73) Assignee: Agency For Science, Technology And Research, Singapore (SG)

(21) Appl. No.: 12/746,401

(22) PCT Filed: Dec. 7, 2007
(86) PCT No.: PCT/SG07/00421

§ 371 Date: Sep. 28, 2010

(51) Int. Cl. H01L 29/792; H01L 21/28

(52) U.S. Cl. 257/325; 438/591; 257/E29.309; 257/E21.21

(57) ABSTRACT

A memory cell is provided. The memory cell comprises a first wire shaped channel structure; and a charge trapping structure surrounding the perimeter surface of the first wire shaped channel structure, the charge trapping structure comprising two charge trapping partial to structures, wherein each charge trapping partial structure is formed of a different material capable of storing electrical charges. Methods of manufacturing the memory cell are also provided.

### FIELD OF THE INVENTION

The present invention relates to a memory cell and methods of manufacturing thereof.

### BACKGROUND OF THE INVENTION

There is a limit in scaling conventional NAND-type nonvolatile flash memory devices beyond 50 nm, due to factors such as loss in floating gate capacitance coupling efficiency, data retention and reliability.

There are SONOS (silicon oxide nitride oxide silicon) structures, which are used because they are less sensitive to capacitive coupling issues and utilize thinner gate stacks, while there are FinFET (fin structure field effect transistors) structures that offer excellent electrostatic control of a short-channel body.

For instance, a conventional semiconductor device has a twin nanowire channel structure formed on a mounting surface of a silicon substrate, where both the nanowires are spaced laterally apart on the mounting surface. A gate region is formed above the mounting surface and around the exposed surfaces of the nanowires adjacent to the portions of the nanowires on the silicon substrate mounting surface.

However, the nanowire arrangement of the known semiconductor device occupies larger surface area on the mounting surface of the silicon substrate. Additionally, it would also be advantageous to provide a memory device with faster programming/erasing speeds, a wide memory window and stable data retention capability.

### SUMMARY OF THE INVENTION

In an embodiment of the invention, there is provided a memory cell including: a first wire shaped channel structure; and a charge trapping structure surrounding the perimeter surface of the first wire shaped channel structure, the charge trapping structure including two charge trapping partial structures, wherein each charge trapping partial structure is formed of a different material capable of storing electrical charges.

In an embodiment of the invention, there is provided a method of forming a memory cell including the steps of forming a first wire shaped channel structure; and forming a charge trapping structure surrounding the perimeter surface of the first wire shaped channel structure, the charge trapping structure including two charge trapping partial structures, wherein each charge trapping partial structure is formed of a different material capable of storing electrical charges.

In an embodiment of the invention, there is provided a method of forming a memory cell, the method including the steps of: forming from a single conducting layer a first wire shaped channel structure and a second wire shaped channel structure; and forming a gate region around the perimeter surface of the first wire shaped channel structure and the perimeter surface of the second wire shaped channel structure; wherein the second wire shaped channel structure is spaced a greater distance from a mounting surface of the gate region than the distance the first wire shaped channel structure is spaced from the mounting surface of the gate region.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a portion of a memory cell built in accordance with an embodiment of the invention.

FIG. 1B shows a cross-sectional view of a portion of a memory cell built in accordance with an embodiment of the invention.

FIG. 2A shows a cross-sectional view of a portion of a memory cell built in accordance with an embodiment of the invention.

FIG. 2B shows a cross-sectional view of a portion of a memory cell built in accordance with an embodiment of the invention.

FIG. 2(I) shows a cross section of a circular channel structure.

FIG. 3 shows a perspective view of the structure of a memory cell built in accordance to an embodiment of the present invention.

FIGS. 4A to 4E show perspective views of several stages to fabricate a memory cell according to an embodiment of the present invention.

FIG. 5A shows a flow chart of a fabrication process.

FIG. 5B shows a flow chart of a fabrication process.

FIG. 6 shows a flow chart of a fabrication process.

FIG. 7 shows an atomic force microscope (AFM) image of nanocrystals formed on a 1×1 μm² surface area of a silicon nitride (Si₃N₄) layer.

FIG. 8 shows a tilted top view of a scanning electron microscopy (SEM) image of twin nanowires after silicon nanocrystals formation.

FIG. 9 shows a tilted top view of a SEM image of twin nanowires on a Si₃N₄ layer of a non-TLE (Trap Layer Engineered) device.

FIG. 10 shows a tilted top view of a SEM image of an isolated TLE SONOS single device after gate electrode definition.

FIG. 11 shows a Transmission Electron Microscopy (TEM) image of the cross section of a SONOS device.

FIG. 12 shows a TEM image of the cross section of a silicon (Si) nanowire.

FIG. 13 shows a plot of drain current I_{d} (in μA) versus gate voltage V_{g} (in V) for vertically stacked twin Si nanowires.

FIGS. 14A and 14B respectively show the programming characteristics of 5 nm and 8 nm diameter TLE SONOS twin nanowire memory cells.

FIGS. 15A and 15B respectively show the erasing characteristics of 5 nm and 8 nm diameter TLE SONOS twin nanowire memory cells.

FIG. 16 compares the P/E speed characteristics and the threshold voltage Δ Vₜₕ shift for twin nanowire devices.

FIGS. 17A and 17B respectively show the programming and erasing (P/E) characteristics of a non-TLE SONOS twin nanowire memory cell.

FIG. 18 compares the P/E speed characteristics and the Δ Vₜₕ shift for memory cells with TLE SONOS and non-TLE SONOS structures.

FIG. 19 shows a plot of current in the linear region with low drain bias V_{d}, I_{dLin} (in μV) versus gate voltage V_{g} (in V) for vertically stacked twin Si nanowires.

FIG. 20A shows a band diagram for a memory cell with a non-TLE SONOS nanowire structure.

FIG. 20B shows a band diagram for a memory cell with a TLE SONOS nanowire structure.

FIG. 21 shows the data retention characteristics of programmed state (PGM) and erased state (ERS) memory cells with a TLE SONOS and a non-TLE SONOS structure.

FIG. 22 shows endurance characteristics of memory cells with a TLE SONOS and a non-TLE SONOS structure.

FIG. 23A shows the programming and erasing (PIE) characteristics of a memory cell.

### DETAILED DESCRIPTION

Exemplary embodiments of a semiconductor memory cell are described in detail below with reference to the accompanying figures. It will be appreciated that the exemplary embodiments described below can be modified in various aspects without changing the essence of the invention.

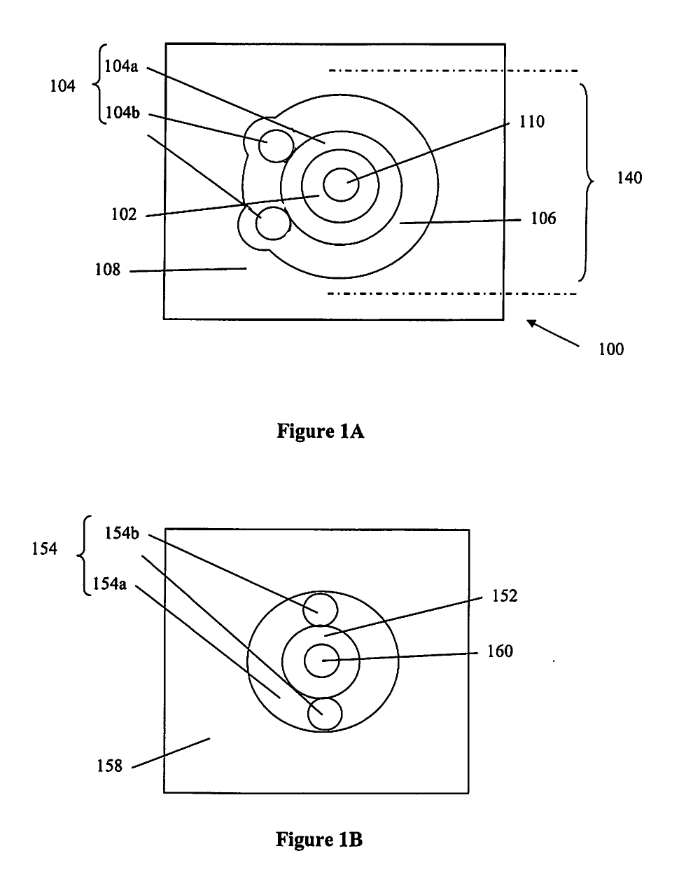

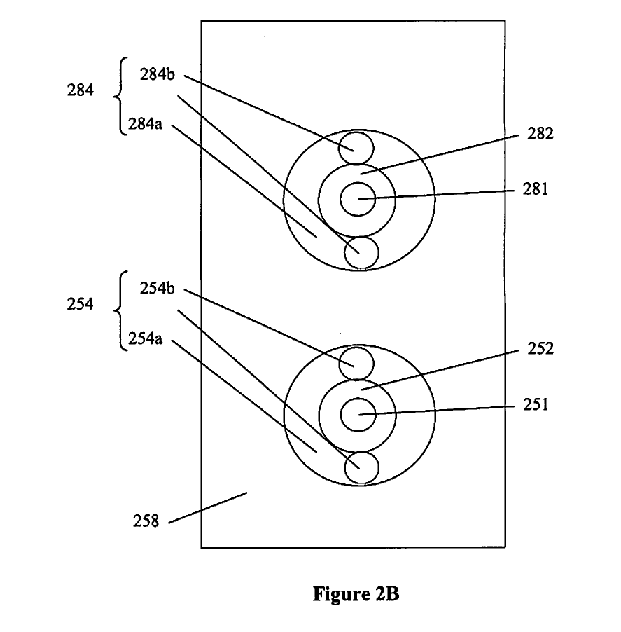

FIG. 1A shows a cross-sectional view 100 of a portion of a memory cell (not shown, but compare memory cell 300 of FIG. 3) built in accordance with an embodiment of the invention.

In the embodiment of the invention shown in FIG. 1A, the memory cell includes a first wire shaped channel structure 110, a first tunneling layer 102, a charge trapping structure 104, a first blocking structure 106 and a gate region 108.

The charge trapping structure 104 surrounds the perimeter surface of the first wire shaped channel structure 110, where the first tunneling layer 102 surrounds the perimeter surface of the first wire shaped channel structure 110 so that the first tunneling layer 102 is disposed between the perimeter surface of the first wire shaped channel structure 110 and the charge trapping structure 104.

The charge trapping structure 104 includes two charge trapping partial structures 104a and 104b, wherein each charge trapping partial structure 104a and 104b is formed of a different material capable of storing electrical charges. The two charge trapping partial structures 104a and 104b may respectively be a first charge trapping layer 104a surrounding the perimeter surface of the first tunneling layer 102; and one or more first nanocrystals 104b surrounding the perimeter surface of the first charge trapping layer 104a.

The gate region 108 surrounds the perimeter surface of the charge trapping structure 104, where the first blocking structure 106 is disposed between the first charge trapping layer 104a and the gate region 108 on portions of the first charge trapping layer 104a not in contact with the one or more first nanocrystals 104b.

It will be appreciated that the first wire shaped channel structure 110 connects the source and drain regions (not shown, but compare both source region 304 and drain region 306 in FIG. 3) of the memory cell to provide a channel for charge carriers flowing between the source and the drain regions.

Having thus provided a Gate-All-Around (GAA) structure for the gate region 108 facilitates further device scalability of the memory cell, compared to current floating gate memory cells, as the GAA structure offers better electrostatic control of the shorter channel body in the first wire shaped channel structure 110. Additionally, the charge trapping structure 104 of the first charge trapping layer 104a and the one or more first nanocrystals 104b acts as a form of trap layer engineering (TLE) to provide a charge storage medium, where the one or more first nanocrystals 104b provide further charge trapping performance enhancement by increasing the memory window provided by the first charge trapping layer 104a. The collective structure 140 (the first wire shaped channel structure 110; the tunneling layer 102; the charge trapping structure 104; and the first blocking structure 106), together with the gate region 108 form a GAA vertically stacked memory cell (compare memory cell 300 of FIG. 3). The trap layer engineered nanowire structure, enables fast programming/erasing speeds and a wide memory window, along with device reliability.

FIG. 1B shows a cross-sectional view 150 of a portion of a memory cell (not shown, but compare memory cell 300 of FIG. 3) built in accordance with an embodiment of the invention.

In the embodiment of the invention shown in FIG. 1B, the memory cell includes a first wire shaped channel structure 160, a first tunneling layer 152, a charge trapping structure 154 and a gate region 158.

The charge trapping structure 154 surrounds the perimeter surface of the first wire shaped channel structure 160, where the first tunneling layer 152 surrounds the perimeter surface of the first wire shaped channel structure 160 so that the first tunneling layer 152 is disposed between the perimeter surface of the first wire shaped channel structure 160 and the charge trapping structure 154.

The charge trapping structure 154 includes two charge trapping partial structures 154a and 154b, wherein each charge trapping partial structure 154a and 154b is formed of a different material capable of storing electrical charges. The two charge trapping partial structures 154a and 154b may respectively be a first charge trapping layer 154a surrounding the perimeter surface of the first tunneling layer 152; and one or more first nanocrystals 154b embedded in the first charge trapping layer 154a.

When using silicon for the one or more embedded first nanocrystals 154b, then a silicon-rich silicon nitride layer 154a may have to be used, where embedding may be performed at a temperature of about 1000° C.

The gate region 158 surrounds the perimeter surface of the charge trapping structure 154 so that the charge trapping structure 154 is disposed between the first tunneling layer 152 and the gate region 158.

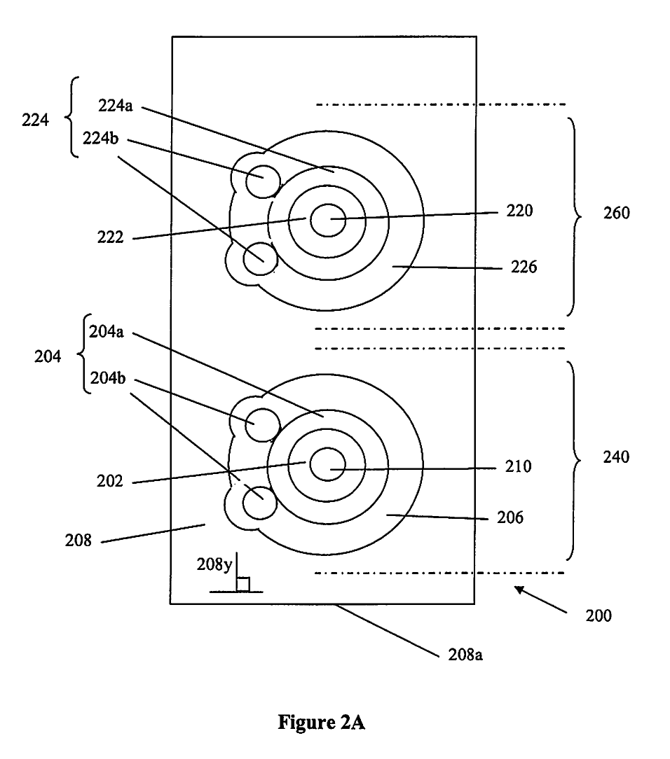

FIG. 2A shows a cross-sectional view 200 of a portion of a memory cell 300 (FIG. 3) built in accordance with an embodiment of the invention. It will be appreciated that FIG. 2A shows the cross-sectional view, taken along plane A-A′ of FIG. 3, of a portion of the memory cell 300 (FIG. 3) built in accordance with the embodiment of the invention.

Similar to the embodiment of the invention shown in FIG. 1A, the memory cell 300 (FIG. 3) includes a first wire shaped channel structure 210, a first tunneling layer 202, a charge trapping structure 204, a first blocking structure 206 and a gate region 208.

The charge trapping structure 204 surrounds the perimeter surface of the first wire shaped channel structure 210, where the first tunneling layer 202 surrounds the perimeter surface of the first wire shaped channel structure 210 so that the first tunneling layer 202 is disposed between the perimeter surface of the first wire shaped channel structure 210 and the charge trapping structure 204.

The charge trapping structure 204 includes two charge trapping partial structures 204a and 204b, wherein each charge trapping partial structure 204a and 204b is formed of a different material capable of storing electrical charges. The two charge trapping partial structures 204a and 204b are respectively a first charge trapping layer 204a surrounding the perimeter surface of the first tunneling layer 202; and one or more first nanocrystals 204b surrounding the perimeter surface of the first charge trapping layer 204a.

Additionally, the memory cell 300 (FIG. 3) includes a second wire shaped channel structure 220, a second tunneling layer 222, a further charge trapping structure 224, and a second blocking structure 226.

The further charge trapping structure 224 surrounds the perimeter surface of the second wire shaped channel structure 220, where the second tunneling layer 222 surrounds the perimeter surface of the second wire shaped channel structure 220 so that the second tunneling layer 222 is disposed between the perimeter surface of the second wire shaped channel structure 220 and the further charge trapping structure 224.

The further charge trapping structure 224 includes two further charge trapping partial structures 224a and 224b, wherein each further charge trapping partial structure 224a and 224b is formed of a different material capable of storing electrical charges. The two charge trapping partial structures 224a and 224b may respectively be a second charge trapping layer 224a surrounding the perimeter surface of the second tunneling layer 222; and one or more second nanocrystals 224b surrounding the perimeter surface of the second charge trapping layer 224a.

The gate region 208 surrounds the perimeter surface of the charge trapping structure 204 and the perimeter surface of the further charge trapping structure 224. The first blocking structure 206 is disposed between the first charge trapping layer 204a and the gate region 208 on portions of the first charge trapping layer 204a not in contact with the one or more first nanocrystals 204b. Similarly, the second blocking structure 226 is disposed between the second charge trapping layer 224a and the gate region 208 on portions of the second charge trapping layer 224a not in contact with the one or more second nanocrystals 224b. The second wire shaped channel structure 220 is spaced a greater distance from a mounting surface 208a of the gate region 208 than the distance the first wire shaped channel structure 210 is spaced from the mounting surface 208a of the gate region 208.

Longitudinal axes (i.e. axes moving directly into the plane of the paper) of the first wire shaped channel structure 210 and the second wire shaped channel structure 220 may be substantially parallel with the mounting surface 208a of the gate region 208. Further, the longitudinal axes of the first wire shaped channel structure 210 and the second wire shaped channel structure 220 may be substantially perpendicular to an axis 208y normal to the mounting surface 208a of the gate region 208. In this manner, the first wire shaped channel structure 210 and the second wire shaped channel structure 220 are arranged to form a vertical stack with respect to the mounting surface 208a of the gate region 208. By arranging the wire shaped channel structures 210 and 220 in a vertically stacked orientation, the wire shaped channel structures 210 and 220 will have less “foot print” on the corresponding mounting surface of a silicon substrate (see mounting surface 302a of support substrate 302 of FIG. 3) to which the gate region 208 is mounted thereto, i.e. the wire shaped channel structures 210 and 220 occupy less surface mounting area of the silicon substrate, when compared to a known semiconductor device having both channel structures placed onto the silicon substrate mounting surface. While having a “foot print” area of a single wire shaped structure on the mounting surface of the silicon substrate, the vertically stacked first wire shaped channel structure 210 and the second wire shaped channel structure 220 provide a higher memory program/erase sensitivity by allowing more bits of memory data to be stored.

It will be appreciated that the first wire shaped channel structure 210 and the second wire shaped channel structure 220 connect the source region 304 (FIG. 3) and drain region 306 (FIG. 3) of the memory cell 300 (FIG. 3) to provide a channel for charge carriers flowing between the source and the drain regions.

Having thus provided a Gate-All-Around (GAA) structure for the gate region 208 facilitates further device scalability of the memory cell 300 (FIG. 3), compared to current floating gate memory cells, as the GAA structure offers better electrostatic control of the shorter channel body in the first wire shaped channel structure 210 and the second wire shaped channel structure 220. Additionally, the charge trapping structure 204 of the first charge trapping layer 204a and the one or more first nanocrystals 204b, along with the further charge trapping structure 224 of the second charge trapping layer 224a and the one or more second nanocrystals 224b, act as forms of trap layer engineering (TLE) to provide charge storage mediums. The one or more first nanocrystals 204b and the one or more second nanocrystals 224b provide further charge trapping performance enhancement by increasing the memory window provided by the respective first charge trapping layer 204a and the second charge trapping layer 224a. The first collective structure 240 (the first wire shaped channel structure 210; the first tunneling layer 202; the charge trapping structure 204; and the first blocking structure 206), the second collective structure 260 (the second wire shaped channel structure 220; the second tunneling layer 222; the further charge trapping structure 224; and the second blocking structure 226) and the gate region 208 form a GAA vertically stacked memory cell 300 (FIG. 3). The trap layer engineered nanowire structure, enables fast programming/erasing speeds and a wide memory window, along with device reliability.

FIG. 2B shows a cross-sectional view 250 of a portion of a memory cell (not shown, but compare memory cell 300 of FIG. 3) built in accordance with an embodiment of the invention.

Similar to the embodiment of the invention shown in FIG. 1B, the memory cell includes a first wire shaped channel structure 251, a first tunneling layer 252, a charge trapping structure 254 and a gate region 258.

The charge trapping structure 254 surrounds the perimeter surface of the first wire shaped channel structure 251, where the first tunneling layer 252 surrounds the perimeter surface of the first wire shaped channel structure 251 so that the first tunneling layer 252 is disposed between the perimeter surface of the first wire shaped channel structure 251 and the charge trapping structure 254.

The charge trapping structure 254 includes two charge trapping partial structures 254a and 254b, wherein each charge trapping partial structure 254a and 254b is formed of a different material capable of storing electrical charges. The two charge trapping partial structures 254a and 254b may respectively be a first charge trapping layer 254a surrounding the perimeter surface of the first tunneling layer 252; and one or more first nanocrystals 254b embedded in the first charge trapping layer 254a.

When using silicon for the one or more embedded first nanocrystals 254b, then a silicon-rich silicon nitride layer 254a may have to be used, where embedding may be performed at a temperature of about 1000° C.

Additionally, the memory cell includes a second wire shaped channel structure 281, a second tunneling layer 282 and a further charge trapping structure 284.

The further charge trapping structure 284 surrounds the perimeter surface of the second wire shaped channel structure 281, where the second tunneling layer 282 surrounds the perimeter surface of the second wire shaped channel structure 281 so that the second tunneling layer 282 is disposed between the perimeter surface of the second wire shaped channel structure 281 and the further charge trapping structure 284.

The further charge trapping structure 284 includes two further charge trapping partial structures 284a and 284b, wherein each further charge trapping partial structure 284a and 284b is formed of a different material capable of storing electrical charges. The two further charge trapping partial structures 284a and 284b may respectively be a second charge trapping layer 284a surrounding the perimeter surface of the second tunneling layer 282; and one or more second nanocrystals 284b embedded in the second charge trapping layer 284a.

When using silicon for the one or more embedded second nanocrystals 284b, then a silicon-rich silicon nitride layer 284a may have to be used, where embedding may be performed at a temperature of about 1000° C.

The gate region 258 surrounds the perimeter surface of the charge trapping structure 254 and the perimeter surface of the further charge trapping structure 284. In this manner, the charge trapping structure 254 is disposed between the first tunneling layer 251 and the gate region 258, while the further charge trapping structure 284 is disposed between the second tunneling layer 282 and the gate region 258.

In the embodiments of the invention, the first wire shaped channel structure (110, 210), the second wire shaped channel structure (220), or both the wire shaped channel structures are nanowires.

By using wire shaped channel structures in the embodiments of the invention, a better electrical equivalent oxide thickness (EOT), εₒₓ, is obtained for the same physical thickness, Tₒₓ, of a planar shaped channel structure.

For the planar shaped channel structure, capacitance, Cₒₓ, is determined by the equation:

Cₒₓ=εₒₓ/T_{ox;}

There is no field enhancement effect.

On the other hand, for a circular channel structure 280, cross section shown in FIG. 2(I), an inner channel 270 surface potential change is determined by the electric field 272 induced by dielectric 274 (analogous to the gate region 108, 208) surrounding the inner channel 270 surface and a charge trapping layer 276 (analogous to the first/second charge trapping layers 104a, 204a and 224a). Electrical field 272 line termination effects, from a positive charge to a respective negative charge, is enhanced due to the circular shape of the charge trapping layer 276. Thus, for a given voltage, the resulting field in the circular channel structure 280 is higher, in comparison with planar case. As there is electrical field 272 enhancement, more surface potential changes are present on the inner channel 270 than compared with a planar channel. Having more surface potential charges in turn induces a greater potential charge, Q. From the equation

q=CₒₓΔV

it will be appreciated that a higher Cₒₓ will be obtained in the circular channel structure 280 due to the greater potential charge Q generated for the same voltage, ΔV, applied to the planar device. In this regard, a smaller circular channel structure can be employed to achieve the same results of a larger planar channel, i.e. reduction in the EOT of the circular channel structure 280 is possible by thinning the inner channel 270.

For the embodiments of the invention, any one or more of a group of conductive materials of poly-silicon, tantalum nitride, titanium nitride, hafnium nitride, aluminum and tungsten may respectively be used for the gate regions (108, 158, 208 and 258). To achieve an n-type memory cell for the embodiments of the invention, the gate regions (108, 158, 208 and 258) may respectively be doped with any one or more of a group of n-type dopants consisting of phosphorus, arsenic and antimony. On the other hand, to achieve a p-type memory cell for the embodiments of the invention, the gate regions (108, 158, 208 and 258) may be doped with any one or more of a group of p-type dopants consisting of boron, aluminum, gallium and indium. Any one or more of a group consisting of silicon and germanium may be used for both the first wire shaped channel structure (110, 160, 210 and 251) and the second wire shaped channel structure (220, 281). For the embodiments of the invention, any dielectric material may be used, for example silicon dioxide (SiO₂), for both the first tunneling layer (102, 152, 202 and 252) and the second tunneling layer (222, 282). For the embodiments of the invention, any one or more of a group of high dielectric materials of silicon nitride (Si₃N₄), hafnium dioxide (HfO₂) and aluminum oxide (Al₂O₃) may respectively be used for both the first charge trapping layer (104a, 154a, 204a and 254a) and the second charge trapping layer (224a, 284a) while any one or more of a group of metals of silicon nanocrystals (Si—NC), germanium nanocrystals and tungsten nanocrystals may respectively be used for both the one or more first nanocrystals (104a, 154a, 204b and 284b) and the one or more second nanocrystals (224b, 284b). For the embodiments of the invention, SiO₂ may respectively be used for both the first blocking structure (106, 206) and the second blocking structure 226. To form an ONO (oxide nitride oxide) structure, SiO₂, Si₃N₄ and SiO₂ may be respectively used for the first tunneling layer (102, 202), the first/second charge trapping layer (104a/204a, 224a) and the the second tunneling layer (222). It will also be appreciated that in the embodiments of the invention, other materials with conduction and valence bands that are lower than the respective tunneling layer and the blocking structure can be used for the charge trapping layers. For instance, when SiO₂ is used for both the the first tunneling layer (102, 152, 202 and 252) and the the second tunneling layer (222, 282), materials such as HfO₂ and Al₂O₃ may be used, where HfO₂ and Al₂O₃ have smaller bandgap energy, but have a better trap charging capability than SiO₂

Returning to the embodiment of the invention shown in FIG. 2A, the collective structures 240 and 260 are also respectively termed as the first and the second trap layer engineered silicon oxide nitride oxide silicon (TLE SONOS) structures when silicon is respectively used for the first and second wire shaped channel structure 210 and 220; silicon dioxide is respectively used for the first and the second tunneling layers 202 and 222; silicon nitride is respectively used for the first and the second charge trapping layers 204a and 224a; silicon nanocrystals are respectively used for the one or more first and second nanocrystals 204b and 224b; silicon dioxide is respectively used for the first and the second blocking structures 206 and 226; and polysilicon is respectively used for the gate region 208.

FIG. 3 shows a perspective view of the structure of a memory cell 300 built in accordance to an embodiment of the present invention. However, it will be appreciated that the present invention also has other applications in the electronics field.

The memory cell 300 includes a support substrate 302 formed of buried oxide (BOX), a source region 304, a drain region 306, the first and the second TLE SONOS structures 240 and 260, and a gate structure 308 that includes the gate region 208 (FIG. 2A). In the context of the memory cell 300, the gate structure 308 refers to the portion of the portions of both the first and the second TLE SONOS structures 240 and 260 that are surrounded by the gate region 208 and also the gate region 208.

The source region 304 and the drain region 306 are spaced apart from each other on a portion of a mounting surface 302a of the support substrate 302, where the source region 304 and the drain region 306 are both in contact with the support substrate 302.

The first TLE SONOS structure 240 connects the source region 304 and the drain region 306 together, so that one end of the first wire shaped channel structure 210 is integral with the source region 304, while an opposite end of the first wire shaped channel structure 210 is integral with the drain region 306. The second TLE SONOS structure 260 also connects the source region 304 and the drain region 306 together, so that one end of the second wire shaped channel structure 220 is integral with the source region 304, while an opposite end of the second wire shaped channel structure 220 is integral with the drain region 306.

In this manner the first wire shaped channel structure 210 and the second wire shaped channel structure 220 establish an electrical connection between the source region 304 and the drain region 306, to provide a channel for charge carriers flowing between the source 304 and the drain 306 regions.

It will be appreciated that the mounting surface 208a (FIG. 2A) of the gate region 208 (FIG. 2A) is in contact with a portion of the mounting surface 302a of the support substrate 302, so that the second TLE SONOS structure 260 is spaced a greater distance from the mounting surface 302a of the support substrate 302 than the distance the first TLE SONOS structure 240 is spaced from the mounting surface 302a of the support substrate 302.

There is a gap 320 between the source region 304 surface and the respective gate structure 308 surface that is opposite to the source region 304. Similarly, there is a gap 322 between the drain region 306 surface and the respective gate structure 308 surface that is opposite to the drain region 306.

As the respective ends of the first wire shaped channel structure 210 and the second wire shaped channel structure 220 are integral with the source region 304 and the drain region 306, any one or more of a group consisting of silicon and germanium is used for both the source region 304 and the drain region 306. Also, as the gate structure 308 includes the gate region 208 (FIG. 2A), poly-silicon is used for the gate region 208 (FIG. 2A) of the gate structure 308.

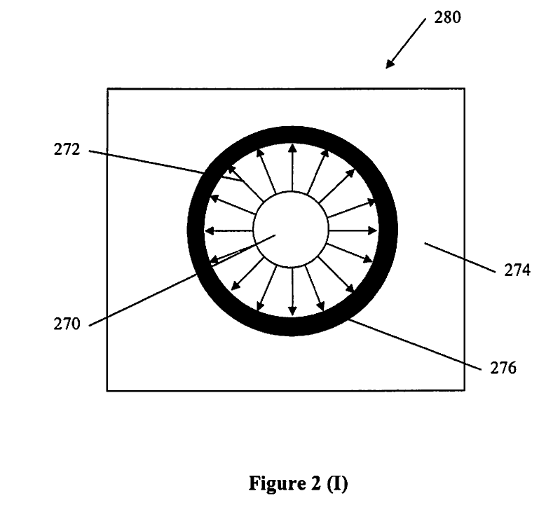

FIGS. 4A to 4E show perspective views of several stages to fabricate the memory cell 300 (FIG. 3) according to an embodiment of the present invention.

The fabrication starts with a silicon-on-insulator (SOI) wafer 400 as a starting substrate in FIG. 4A. However, it will be appreciated that other starting substrates like bulk silicon can be used.

The SOI wafer 400 includes a single conducting layer 402 separated vertically from a bulk support substrate 406 by a buried oxide (BOX) insulating layer 404. The BOX layer 404 electrically isolates the single conducting layer 402 from the bulk support substrate 406 and also acts as a support substrate to the single conducting layer 402. The SOI wafer 400 may be fabricated by any standard techniques, such as wafer bonding or a separation by implantation of oxygen (SIMOX) technique.

The single conducting layer 402 may typically be either silicon and/or germanium from an 8′ wafer, and is around 120 nm thick. However, other semiconductor materials including, but not limited to, poly-silicon and gallium arsenide may be used. The BOX layer 404 may typically be SiO₂ but may be formed from any suitable insulating materials including, but not limited to, tetraethylorthosilicate (TEOS), Silane (SiH₄), silicon nitride (Si₃N₄) or silicon carbide (SiC). The BOX layer 404 is about 1500 Angstrom thick but is not so limited. The bulk support substrate 406 may be formed from any suitable semiconductor materials including, but not limited to Si, sapphire, polysilicon, silicon dioxide (SiO₂) or silicon nitride (Si₃N₄).

A photoresist layer 408 is applied or coated onto the top surface of the single conducting layer 402. The photoresist layer 408 has a fin structure 412 including a fin portion 414 arranged in between two supporting portions 416, where the fin structure 412 may be manufactured by standard photolithography techniques, for example 248 nm krypton fluoride (KrF) lithography. Alternating-Phase-Shift mask (AltPSM) may be used to trim the narrow fin portion 414 to obtain a fin portion width 414w of from about 40 to about 200 nm. Consequently, the shape and size of the first wire shaped channel structure 210 (refer FIG. 4C) and the second wire shaped channel structure 220 (refer FIG. 4C) will be determined by this fin definition.

Subsequently, using the photoresist layer 408 as a mask, portions of the single conducting layer 402 not covered by the mask are etched away using phase shift mask lithography leaving behind a patterned single conducting layer 402b with a fin structure 422 (FIG. 4B) including a fin portion 424 (FIG. 4B) arranged in between two supporting portions 426a and 426b. The fin structure 422 extends the entire thickness 402bt of the patterned single conducting layer 402b (FIG. 4B).

After forming the patterned single conducting layer 402b, the photoresist layer 408 is removed or stripped away by a photoresist stripper (PRS) to produce the structure 410 shown in FIG. 4B. Photoresist stripping, or simply ‘resist stripping’, is the removal of unwanted photoresist layer from a wafer, where the objective is to eliminate the photoresist material from the wafer as quickly as possible, without allowing any surface material under the photoresist to be attacked by the chemicals used. In this regard, any other suitable technique or process may also be used to provide greater flexibility with respect to forming the patterned single conducting layer 402b. FIG. 4B(I) provides a top view of the patterned single conducting layer 402b.

A mask (not shown) is placed onto the upper surface 402bu of the fin structure 422, followed by a self limiting oxidation process of the masked patterned single conducting layer 402b carried out at 850° C. in dry O₂ for 4 hrs. During the oxidation process, there is stress build up in the inner portion of the fin structure 422, which retards the oxidation rate of the inner portion. As the oxidation proceeds with thicker oxide being formed on the outer porter of the fin structure 422, the inner portion of the fin structure 422 will be oxidized at a slower rate than the outer portion structure. This retarded oxidation behavior will help to control the process at which the first wire shaped channel structure 210 and the second wire shaped channel structure 220 are formed and prevents entire oxidation of the first wire shaped channel structure 210 and the second wire shaped channel structure 220. As the upper surface 402bu of the fin structure 422 is masked, it is mainly the exposed portion 402be of the patterned single conducting layer 402b fin portion 424 that is subject to the oxidation process.

The exposed portion 402be of the fin portion 424 may be oxidised in dry O₂ for around 4 hours at about 875° C. The structure 410 may then be treated to a solution of diluted HF so that the first wire shaped channel structure 210 and the second wire shaped channel structure 220, in the form of two vertically stacked Si nanowires, are released from the oxidised fin portion 424, as shown in FIG. 4C. FIG. 4C(I) shows a cross sectional view, taken along plane AA′ of FIG. 4C, of the first wire shaped channel structure 210 and the second wire shaped channel structure 220. The nanowire diameter 450 is about 3 nm to about 20 nm. The twin nanowire structure provides channels that enhance the read current of a memory device. Compared with known laterally formed twin nanowires formed on the surface of support substrate, it will be appreciated that the self limiting oxidation process does not require the use of spacers or an epitaxy process. Rather, the self limiting oxidation process provides the advantage of a single step process to obtain the first wire shaped channel structure 210 and the second wire shaped channel structure 220.

It will be appreciated that the formation of the twin nanowire structure from only the single conducting layer 402 provides for less complicated fabrication as opposed to forming the twin nanowire structure from a multi-layered substrate.

After the first wire shaped channel structure 210 and the second wire shaped channel structure 220 are formed, tunneling oxide layers and charge trapping structures are respectively deposited as shown in FIGS. 4D, 4D(I) and 4D(II). FIG. 4D(I) is a cross sectional view taken along plane AA′ of FIG. 4D, while FIG. 4D(II) is a cross sectional view taken along plane BB′ of FIG. 4D.

Referring to FIGS. 4D(I) and 4D(II), the first tunneling layer 202; the second tunneling layer 222; and a third tunneling layer 432 are respectively deposited, at for example a current rating of about 45A and a temperature of about 720° C. using silane (SiH₄) and nitrogen dioxide (NO₂), around the perimeter surface of the first wire shaped channel structure 210; the perimeter surface of the second wire shaped channel structure 220; and the top surfaces of the support portion 426a. The first tunneling layer 202, the second tunneling layer 222, and the third tunneling layer 432 may be in the form of a thin film of SiO₂ having a common thickness 202t, 222t and 432t of from about 3.0 to about 10 nm. It will be appreciated that the exact thickness of the tunneling layers may be determined by the specific programming/erasing voltage application. Lower voltages require thinner tunneling oxide.

Subsequent to the tunneling layer deposition, the first charge trapping layer 204a; the second charge trapping layer 224a; and a third charge trapping layer 434a are respectively deposited, at for example a current rating of for example around 45A at around 720° C. using dichlorosilane (DCS), around the perimeter surface of the first tunneling layer 202; the perimeter surface of the second tunneling layer 222; and the surface of the third tunneling layer 432. The first charge trapping layer 204a, the second charge trapping layer 224a; and the third charge trapping layer 434a may be in the form of Si₃N₄ having a common thickness 204at, 224at and 434at of from about 3 to about 30 nm. It will be appreciated that the thickness of the charge trapping layers determines the charge trapping efficiency of the memory cell and in turn the programming/erasing data rate. While having a thicker trapping layers allows for more charges to be stored, this increases the overall thickness of the memory cell and also the degree of voltage coupling between the gate region 208 [refer FIG. 4E(I)] surface and the first/second tunneling layers (202, 222).

Finally, the one or more first nanocrystals 204b; the one or more second nanocrystals 224b; and one or more third nanocrystals 434b are respectively deposited around the first charge trapping layer 204a, the second charge trapping layer 224a; and the third charge trapping layer 434a. The first charge trapping layer 204a and the one or more first nanocrystals 204b are also termed as two charge trapping partial structures of the charge trapping layer 204, where the charge trapping layer surrounds the perimeter surface of the first tunneling layer 202. The second charge trapping layer 224a and the one or more second nanocrystals 224b are also termed as two further charge trapping partial structures of the further charge trapping layer 224, where the further charge trapping layer surrounds the perimeter surface of the second tunneling layer 222.

The deposition of the tunneling layers, the charge trapping layer and the one or more nanocrystals may be performed under low pressure chemical vapour deposition (LPCVD), where the silicon nanocrystals may be formed by decomposing silane, SiH₄ into Si and hydrogen H₂ gas. The decomposition may be performed in a furnace using 100-200 cm³/min SiH₄ flow at around 550 to 600° C.

In another embodiment (compare FIG. 2B) of the invention, the one or more first nanocrystals 204b may be embedded within the first charge trapping layer 204a itself, where silicon-rich silicon nitride may be used for the first charge trapping layer 204a. Simultaneously, the one or more second nanocrystals 224b may be embedded within the second charge trapping layer 224a itself, where silicon-rich silicon nitride may be used for the second charge trapping layer 224a. When using silicon for the one or more embedded first nanocrystals 204b, then a silicon-rich silicon nitride layer 204a may have to be used, where embedding may be performed at a temperature of about 1000° C.

Returning to the fabrication of the memory cell 300 (FIG. 3), FIGS. 4E and 4E(I) illustrate the formation of the blocking structures 206 and 226 and the gate structure 308, where FIG. 4E(I) shows the cross-sectional view, taken along plane A-A′ of FIG. 4E.

Referring to FIG. 4E(I), the first blocking structure 206 is deposited on portions of the first charge trapping layer 204a not in contact with the one or more first nanocrystals 204b. Simultaneously, the second blocking structure 226 is deposited on portions of the second charge trapping layer 224a not in contact with the one or more second nanocrystals 224b. Deposition of the first blocking structure 206 and the second blocking structure 226 may be at for example a current rating of about 45A and a temperature of about 720° C. using silane (SiH₄) and nitrogen dioxide (NO₂). The first blocking structure 206 and the second blocking structure 226 may be in the form of a layer of SiO₂ having a common thickness 206t and 226t of around 8 nm. Considering that the equivalent oxide thickness of silicon nitride, ε_{SiN} is around 7, the equivalent oxide thickness (EOT) of the ONO (the first/second tunneling layers 202/222, the first/second charge trapping layers 204a/224a and the first/second blocking structures 206/226) stacks 440 and 442 is from about 100 to about 200 nm.

Subsequently, the gate region 208 is deposited around the perimeter surfaces of the first blocking structure 206 and the second blocking structure 226 to form the Gate-All-Around (GAA) structure 308. In this manner, the first blocking structure 206 is formed between the first charge trapping layer 204a and the gate region 208, while the second blocking structure 226 is formed between the second charge trapping layer 224a and the gate region 208. The gate region 208 may be in the form of polysilicon having thickness 208t of from about 80 to about 200 nm. It will be appreciated that if too thin a polysilicon layer is formed, dopants will penetrate beyond the desired depth of the gate region 208 during the subsequent dopant stage (refer FIG. 4F), while too thick a polysilicon layer will not achieve uniform definition of the gate region 208.

The deposition of the blocking structures and the gate region may be performed under physical vapour deposition (PVD). However, in using PVD to deposit the gate region 208, uneven step-coverage in the form of undesirable shadow effects can occur leading to a non-uniform film formed around the the perimeter surfaces of the first blocking structure 206 and the second blocking structure 226. As a substitute, it will be appreciated that atomic layer deposition (ALD) using titanium nitride may be used.

FIG. 4F illustrates the final stage of the fabrication process, where the fabricated structure is doped to obtain the memory cell 300.

Ion-implantation 480 using, for example phosphorus of concentration around 4×10¹⁵ cm⁻² and at a doping energy level of around 30 keV and at a temperature of around 1000° C. for a duration of around 5 s, defines the source region 304, the drain region 306 and a gate region in the gate structure 308. Standard metallization and sintering (not shown), at a temperature of around 420° C. using 10% hydrogen gas (H₂) concentration for a duration of around 30 min, may then be performed to form contact points for peripheral electronic devices (not shown) to access the memory cell 300.

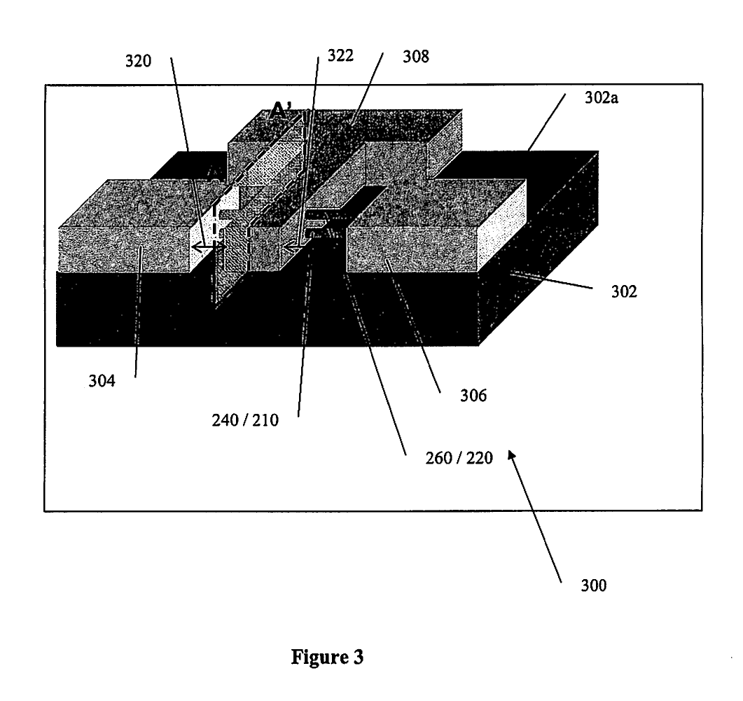

FIG. 5A shows a flow chart 500 of the fabrication process of FIGS. 4A to 4F. As the fabrication process has already been detailed with reference to the description for FIGS. 4A to 4F, only a summary of the flow chart steps is provided below.

In stage 502, the VST-Si nanowire structure (the first wire shaped channel structure 210 [FIG. 4C] and the second wire shaped channel structure 220 [FIG. 4C]) is formed in accordance to the description with reference to FIG. 4A.

In stage 504, ONO structure (tunneling layer/charge trapping layer/blocking structure) in accordance to the description with reference to FIG. 4D.

Gate electrode deposition occurs in stage 506 in accordance to the description with reference to FIG. 4E.

Subsequently, gate patterning and etching occur in stage 508.

Finally and in accordance to the description with reference to FIG. 4F, in stages 510, 512 and 514, implantation and dopant activation; contact etch and metallization; and sintering at a temperature of around 420° C. using 10% hydrogen gas (H₂) concentration for a duration of around 30 min respectively occur.

Broadly, the fabrication process of FIGS. 4A to 4F follows a flow chart 550 shown in FIG. 5B.

In stage 552, the first wire shaped channel structure 210 [FIG. 4C(I)] and the second wire shaped channel structure 220 [FIG. 4C(I)] are formed from the single conducting layer 402 (FIG. 4A).

In stage 554, the gate region 208 [FIG. 4E(I)] is formed around the perimeter surface of the first wire shaped channel structure 210 and the perimeter surface of the second wire shaped channel structure 220.

In the stages 552 and 554, the fabrication is done so that the second wire shaped channel structure 220 is spaced a greater distance from the mounting surface 208a

[FIG. 4E(I)] of the gate region 208 than the distance the first wire shaped channel structure 210 is spaced from the mounting surface 208a of the gate region 208.

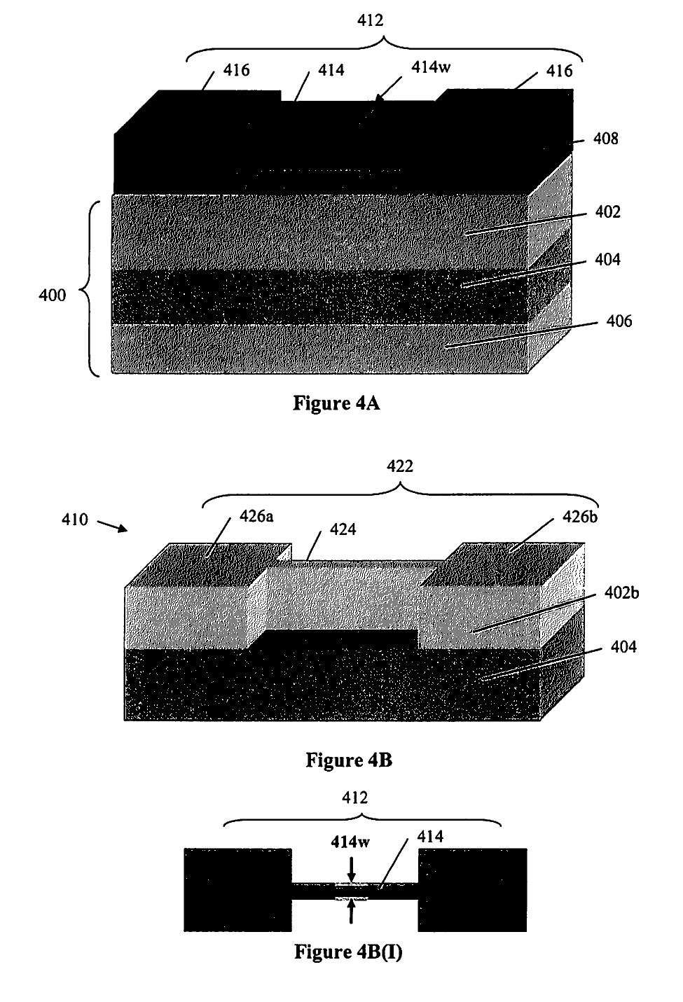

Similarly, to fabricate the memory cell of an embodiment of the invention, a flow chart 600, shown in FIG. 6, is followed.

In stage 602, the first wire shaped channel structure 110 (FIG. 1A) is formed.

In stage 604, the charge trapping structure 104 (FIG. 1A) surrounding the perimeter surface of the first wire shaped channel structure 110 is formed. The charge trapping structure 104 includes the two charge trapping partial structures 104a and 104b, wherein each charge trapping partial structure 104a and 104b is formed of a different material capable of storing electrical charges.

### Microscopic Images of Fabricated Memory Devices

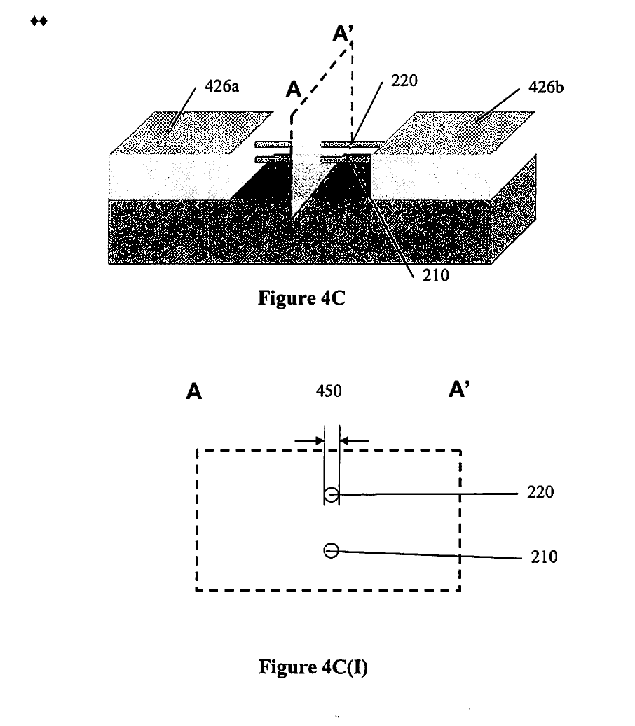

FIGS. 7 to 12 are microscopic images of devices fabricated in accordance with embodiments of the present invention.

FIG. 7 shows an atomic force microscope (AFM) image 700 of nanocrystals 702 formed on a 1×1 μm² surface area of a Si₃N₄ layer 704 in accordance to one embodiment of the invention. The AFM image 700 reveals the formation of the silicon nanocrystals 702 with a dot density of 7.5×10⁹ cm⁻².

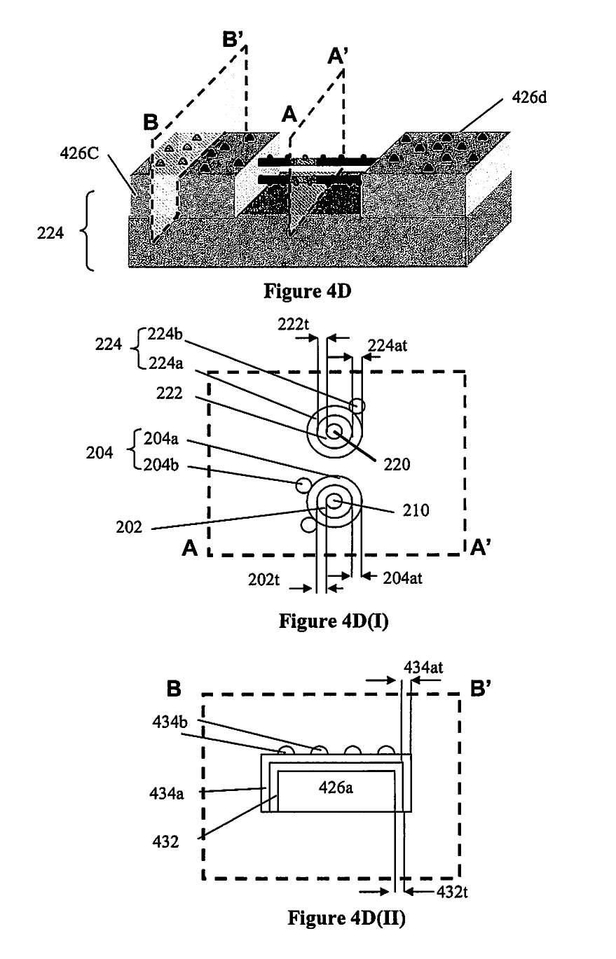

FIG. 8 shows a tilted top view of a scanning electron microscopy (SEM) to image 800 of twin nanowires 802 and 804, of 1 μm length each, after silicon nanocrystals 806 formation on a Si₃N₄ layer 808 to form a trap layer engineered (TLE) device in accordance to one embodiment of the invention.

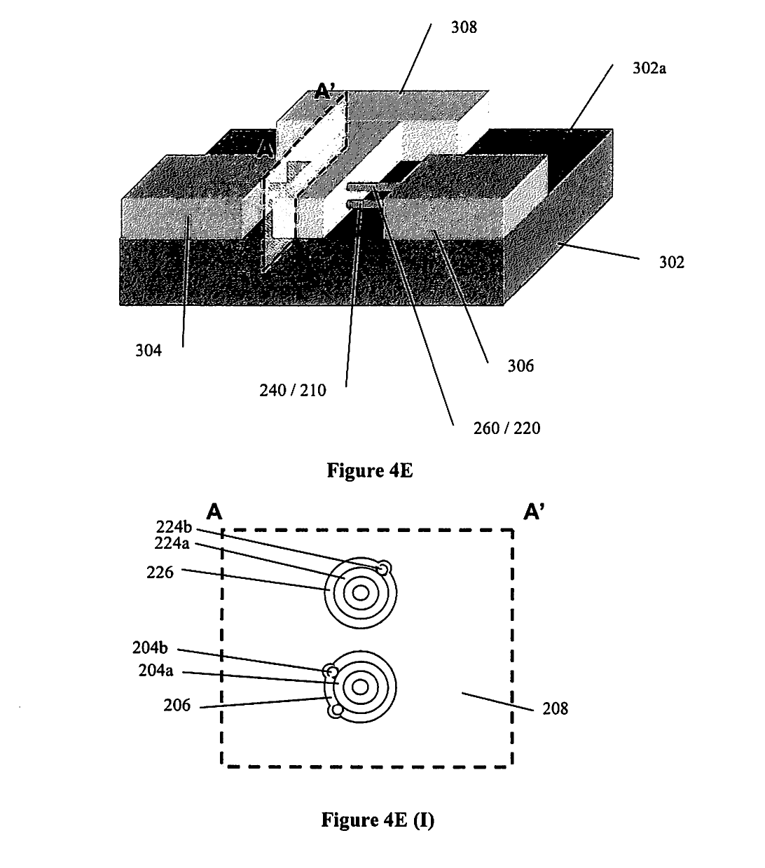

FIG. 9 shows a tilted top view of a SEM image 900 of twin nanowires 902 and 904, of 0.5 μm length each, on a Si₃N₄ layer 908, where no silicon nanocrystals are present, to form a non-TLE device in accordance to one embodiment of the invention.

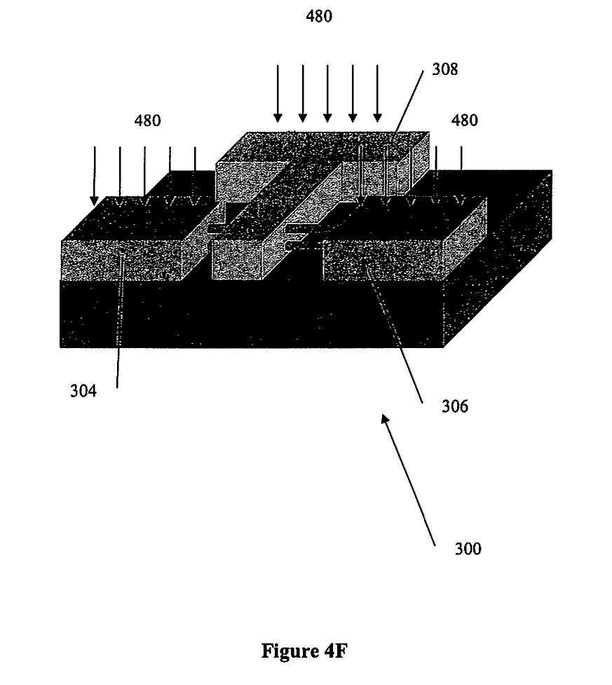

FIG. 10 shows a tilted top view of a SEM image 1000 of an isolated TLE SONOS single device after gate electrode 1002 definition in accordance to one embodiment of the invention. The gate electrode 1002 surrounds the vertical stacked silicon nanowire (VST-SiNW) structure 1010, while the VST-SiNW structure connects the source region 1004 with the drain region 1006.

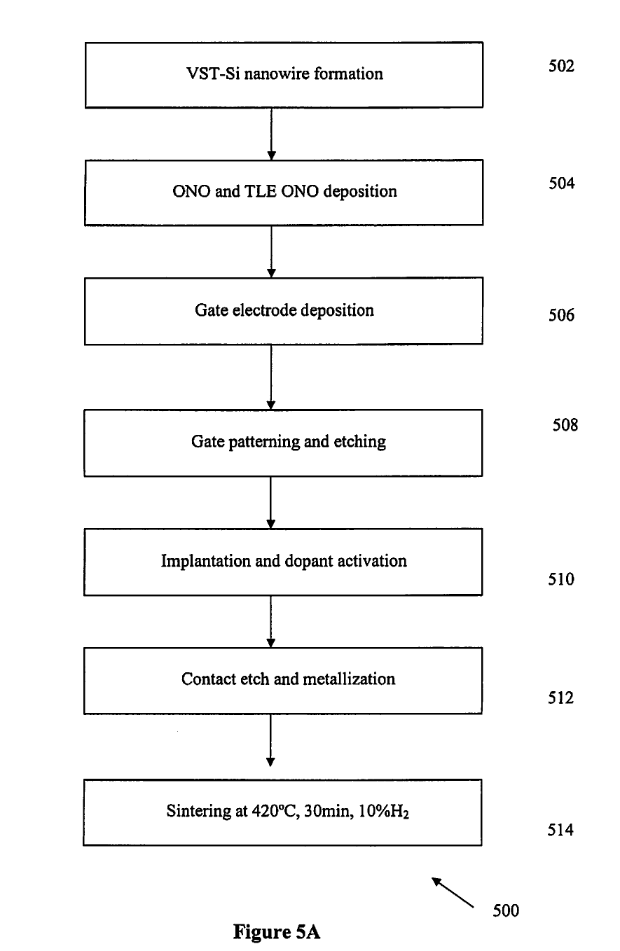

FIG. 11 shows a Transmission Electron Microscopy (TEM) image 1100 of the cross section of a VST SiNW SONOS device 1102 built in accordance to one embodiment of the invention. Two Si nanowires 1104 and their respective surrounding ONO structures 1106, along with a surrounding poly-silicon gate region 1108 can be seen in FIG. 11.

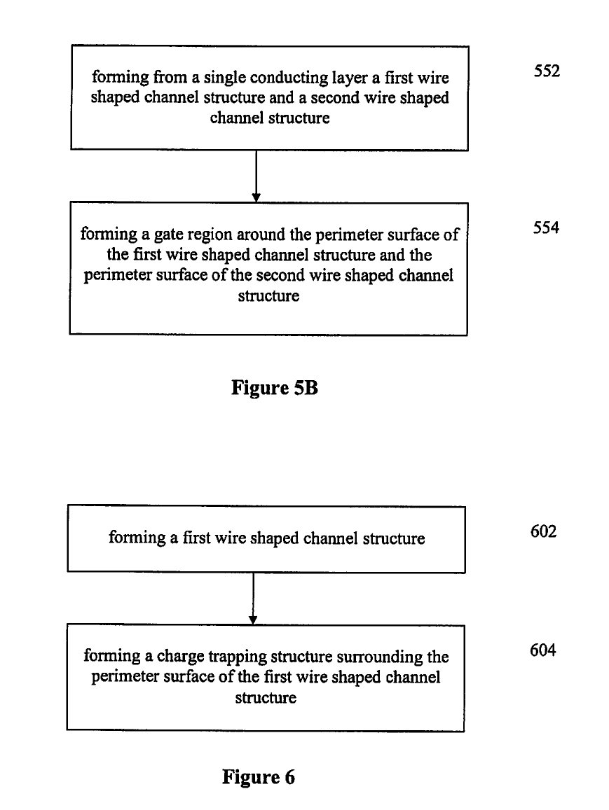

FIG. 12 shows a TEM image 1200 of the cross section of one of the Si nanowires 1104 of FIG. 11. The surrounding ONO structure 1106, in the form of a SiO₂ layer 1202 around the perimeter surface of the Si nanowire 1104, a Si₃N₄ layer 1204 around the perimeter surface of the SiO₂ layer 1202 and another SiO₂ layer 1206 around the perimeter surface of the Si₃N₄ layer 1204. In FIGS. 11 and 12, the nanowire 1104 diameter is around 5 nm, while the ONO structure 1106 has a thickness of around 4.5 nm, 4.5 nm and 8 nm for the SiO₂ layer 1202, the Si₃N₄ layer 1204 and the SiO₂ layer 1206 respectively.

### Experiments and Results

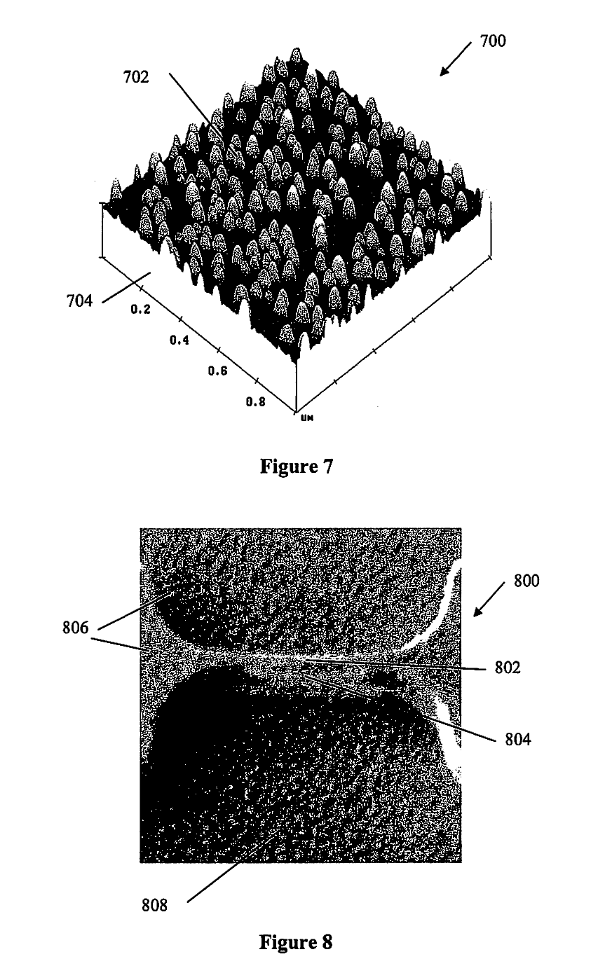

FIG. 13 shows a plot 1300 of drain current I_{d} (in μA) versus gate voltage V_{g} (in V) for vertically stacked twin Si nanowires, each with a gate length L_{g} of around 1 μm and diameter of around 5 nm. Graphs 1302a and 1302b illustrate the I_{d}-V_{g} characteristics for the nanowires with a TLE SONOS structure, while graphs 1304a and 1304b illustrate the I_{d}-V_{g} characteristics for the nanowires with a SONOS structure. Similar to the silicon nanowire field effect transistors (Si—NW FETs) reported in “Ultra-narrow silicon nanowire gate-all-around CMOS devices: Impact of diameter, channel-orientation and low temperature on device performance” by N. Singh et al. in IEDM Tech. Dig., p. 547-560, 2006, the vertically stacked twin Si-nanowire SONOS devices also exhibit excellent transfer characteristics as seen from graphs 1304a and 1304b. The SONOS device [i.e. without the silicon nanocrystals (Si—NC)] is relatively superior to the TLE SONOS in terms of subthreshold (ss) behavior (75 mV/dec vs 84 mV/dec), which could be due to a better interface quality between gate stack layers. The sharp subthreshold turn-on and low DIBL (drain induced barrier lowering), which indicates the amount of threshold voltage shift per drain voltage change, of ≦30 mV/V with EOT=15 nm represents good short channel effect control for the twin nanowire structure channel.

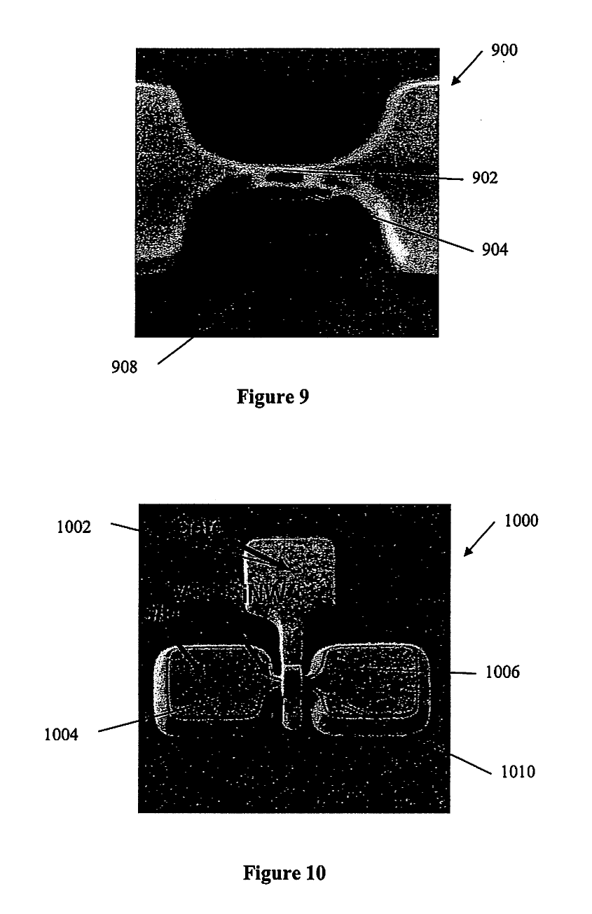

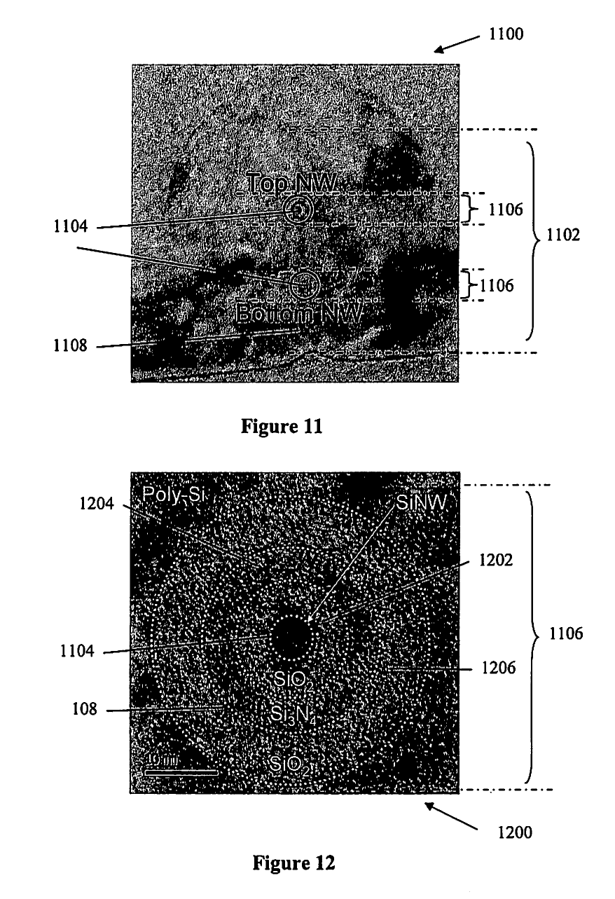

FIGS. 14A and 15A respectively show the programming 1400 and erasing 1450 (P/E) characteristics of a TLE SONOS twin nanowire memory cell, with each nanowire having a diameter of around 5 nm and length L_{g} of around 1 μm, while FIGS. 14B and 15B respectively show the P/E 1500 and 1550 characteristics of a TLE SONOS twin nanowire memory cell, with each nanowire having a diameter of around 8 nm and a length L_{g} of around 1 μm. All P/E were performed using low biasing condition of respectively Vₚ from 6V to 11 V and V_{c} from −6V to −10V applied on the gate. Fowler-Nordheim (FN) injection scheme was used for the channel program and erasure by biasing the gate electrode in positive or negative polarities, with the channel body grounded, and both the source and drain regions grounded.

Programming characteristics for the 5 nm and the 8 nm diameter nanowire devices are respectively shown in FIGS. 14A and 14B for Vₚ=6V, 7V, 8V, 9V, 10V and 11V. On the other hand, erasing characteristics for the 5 nm and the 8 nm diameter nanowire devices are respectively shown in FIGS. 15A and 15B for Vₑ=−6V, −7V, −8V, −9V and −10V.

Faster P/E speed is obtained for the nanowire with diameter of 5 nm. It is observed that faster P/E speed can be achieved up to a threshold voltage, ΔVₜₕ=3.2 V at Vₚ=11 V within 1 μs and at V_{c}=−10 V within 1 ms. The 5 nm diameter nanowire is faster from the scaling of the channel body into a smaller dimension, wherein the width of potential well in the nanowire channel is reduced. The charges being injected in the 5 nm diameter nanowire channel are pushed closer to the interface, further facilitating carrier efficiency in the TLE SONOS nanowire structure.

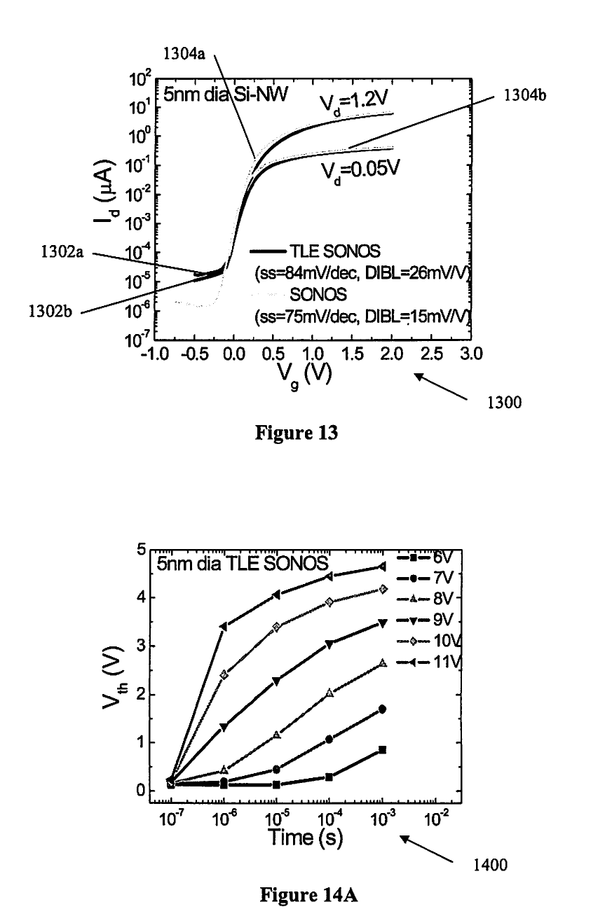

FIG. 16 compares the P/E speed characteristics and the Δ Vₜₕ shift for twin nanowire devices with a diameter 5 nm and 8 nm at Vₚ=9V and Vₑ=−10V. Graphs 1602p and 1602e illustrate the Δ Vₜₕ shift for the 5 nm twin nanowire device, while graphs 1604p and 1604e illustrate the Δ Vₜₕ shift for the 8 nm twin nanowire device. The faster P/E speed of the thinner nanowire device may be attributed to greater vertical electric field strength. It means that the vertical electric field in nanowire structure device is not only related to the EOT of gate dielectrics, as in planar devices, but also associated with the nanowire channel body itself. As the nanowire diameter decreases, i.e., the channel body is scaled, the vertical electric field increases and enhances carriers tunneling. Meanwhile, the energy bandgap widening effect due to quantum mechanics for smaller GAA Si nanowire channel induces a larger amount of tunneling carriers, because the potential barriers that the charges have to overcome are reduced when the conduction band of the channel is lifted up. These effects aid electrons tunneling from the body into the trapping layers and hence improve the P/E speed for the nanowire device.

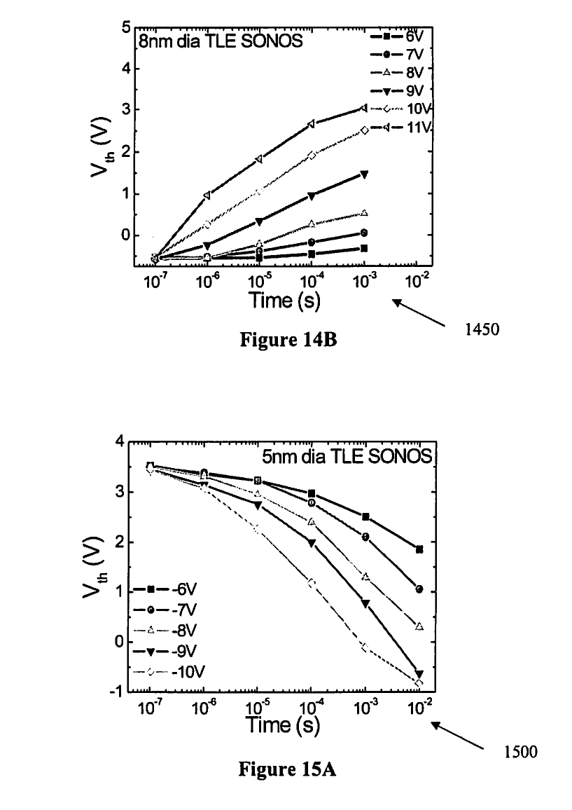

FIGS. 17A and 17B respectively show the programming 1700 and erasing 1750 (PIE) characteristics of a non-TLE SONOS twin nanowire memory cell, with each nanowire having a diameter of around 5 nm and length L_{g} of around 1 μm. All P/E were performed using low biasing condition of respectively Vₚ from 6V to 11 V and Vₑ from −6V to −11V applied on the gate.

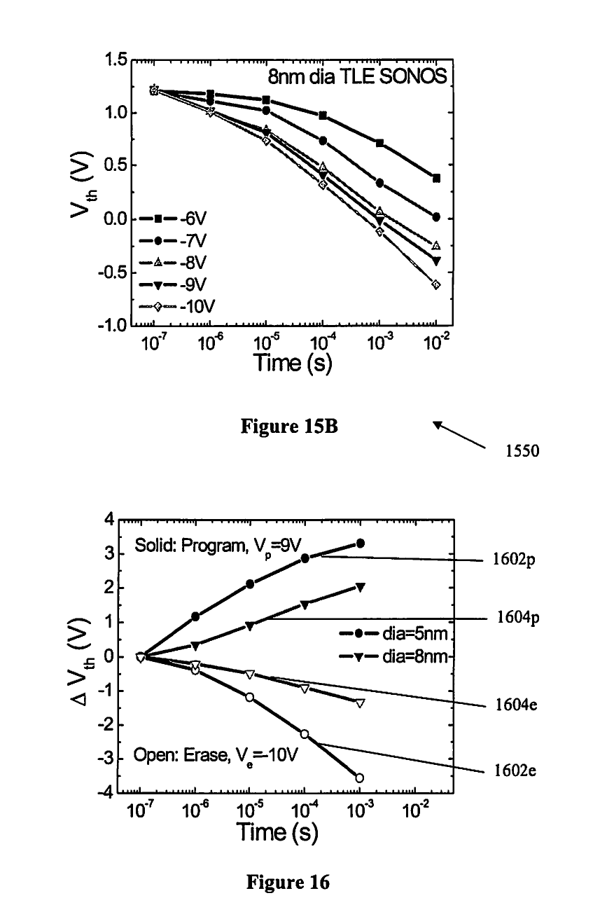

FIG. 18 compares the P/E speed characteristics and the Δ Vₜₕ shift for memory cells with TLE SONOS and non-TLE SONOS structures, both the memory cells having nanowires with same diameters. Graphs 1802p and 1802e refer to the TLE SONOS memory cell, while graphs 1804p and 1804e refer to the non TLE SONOS memory cell. Programming is done at Vₚ=9V and erasing at Vₑ=−10V. The TLE SONOS memory cell has a faster P/E compared with the non-TLE SONOS memory cell.

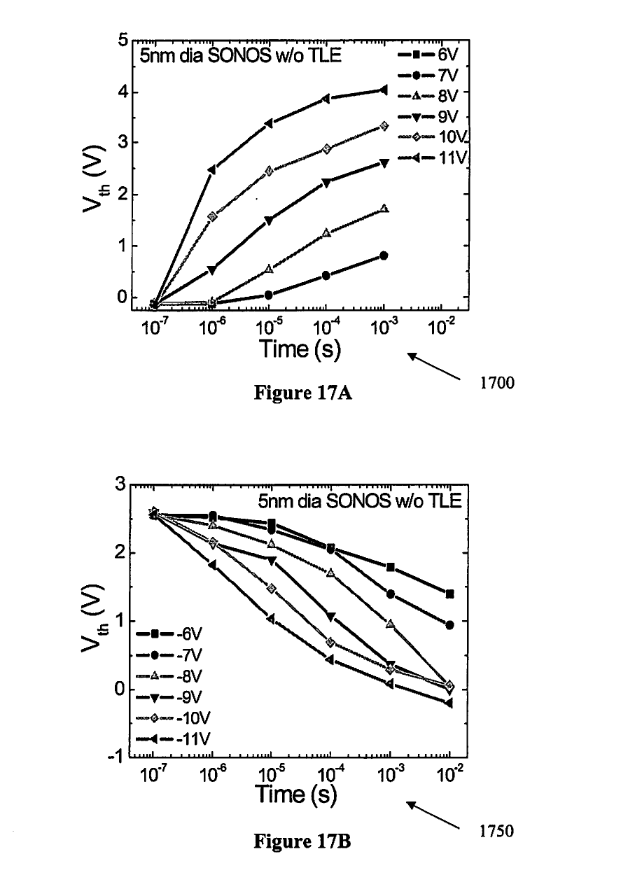

FIG. 19 shows a plot 1900 of current in the linear region with low drain bias V_{d} (around 0.05V), I_{dLin} (in μA) versus gate voltage V_{g} (in V) for vertically stacked twin Si nanowires, each with a length L_{g} of around 1 μm and diameter of around 5 nm. Graphs 1902p and 1902e illustrate the I_{dLin}−V_{g} characteristics for the programmed state (PGM) and the erased state (ERS) respectively for a TLE SONOS structure, while graphs 1904p and 1904e illustrate the I_{dLin}−V_{g} characteristics for the PGM and the ERS respectively for a non-TLE SONOS structure. An enhanced 6.25V PIE window 1906 was obtained for the to TLE SONOS structure, compared with a 4.5V P/E window 1908 of the non-TLE SONOS structure. The larger memory window for the TLE SONOS structure is due to the increased trap density brought about by TLE structure, i.e. the silicon nanocrystals. The density of the trapping centers in the TLE structure is a factor that influences the memory window. A large memory window is necessary for developing multi-level cell technology and in applications to memory operation with more than two bits in a single cell.

Also, Vₜₕ saturation becomes significant when large erasing voltages are applied in SONOS devices, because gate electrons injection neutralizes holes tunneling into the nitride charge trapping layer. However, Vₜₕ saturation is mitigated in erasure operations for TLE SONOS structures. This may be due to the reason that the Si—NC captures more holes during carrier tunneling from the substrate, for the same voltage value where erasure is performed in the non-TLE SONOS structure. Mitigated Vₜₕ saturation in a TLE SONOS structure is advantageous for widening A Vₜₕ during the erase cycle.

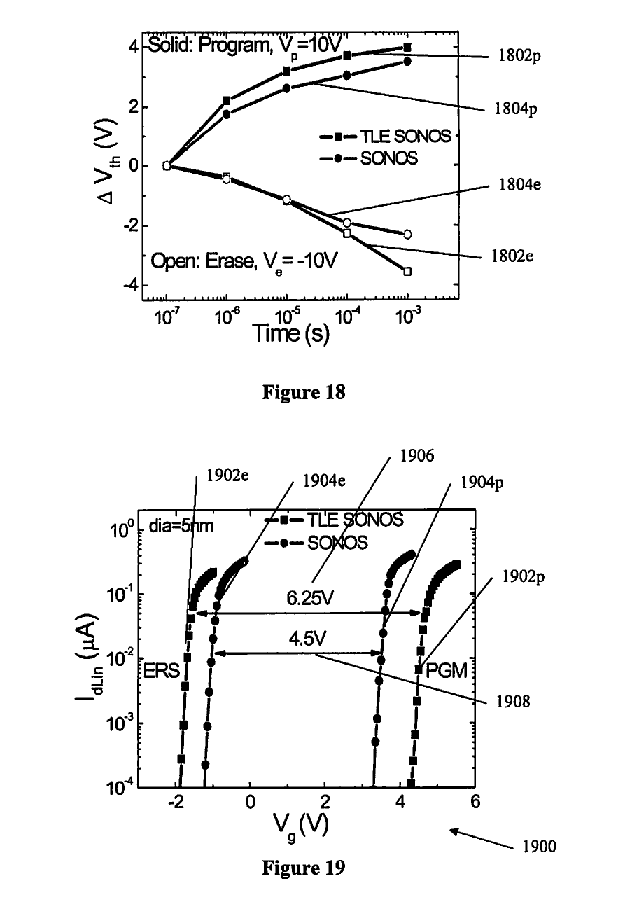

FIG. 20A shows a band diagram 2000 for a memory cell with a non-TLE SONOS nanowire structure, while FIG. 20B shows a band diagram 2050 for a memory cell with a TLE SONOS nanowire structure. Both the non-TLE SONOS and the TLE SONOS device have programming voltages 3.2V applied. The flow of charges across the non-TLE SONOS and the TLE SONOS devices are pictorially depicted using arrows 2002 and 2052 respectively. More charges 2054 (compare 20004) are trapped for the TLE SONOS device due to separately grown Si—NC layer 2056 and conduction band offset 2062 between the Si—NC 2056 and the Si₃N₄ layer 2058. The Si—NC 2056 effectively increases the trap density in the trapping layer 2060, but does not affect device scaling. Since the separately distributed Si—NC 2056 do not sacrifice the EOT of the TLE SONOS structure, applying the Si—NC 2056 is more advantageous than increasing the thickness of the Si₃N₄ layer 2058.

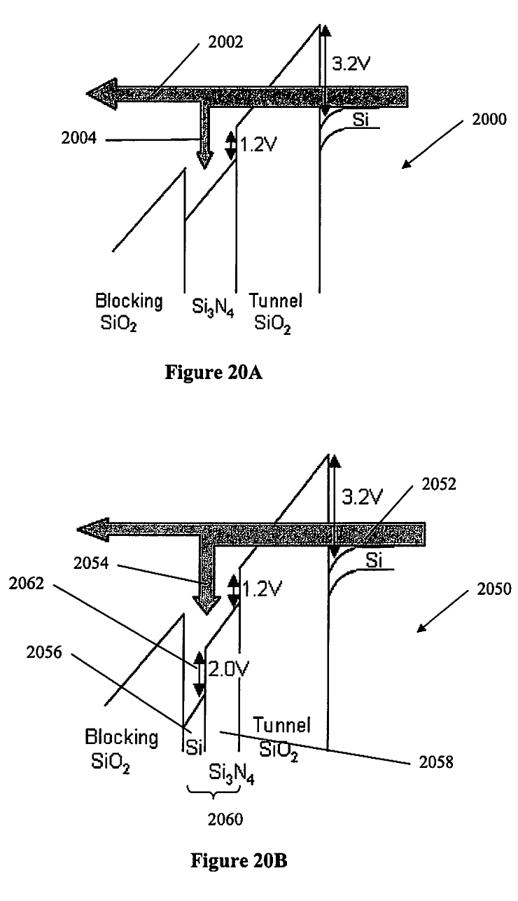

FIG. 21 shows the data retention characteristics (through plotting Vth against time) of programmed state (PGM) and erased state (ERS) memory cells with a TLE SONOS and a non-TLE SONOS structure, both the memory cells having nanowires of same diameters 5 nm. Graphs 2102p and 2102e refer to the TLE SONOS memory cell at a programmed state and an erased state respectively, while graphs 2104p and 2104e refer to the non-TLE SONOS memory cell at a programmed state and an erased state respectively. Programming and erasing for both the TLE SONOS and the non-TLE SONOS devices were performed by applying a gate voltage V_{g}=8V for a duration of 100 μs and a gate voltage V_{g}=−9V for a duration of 1 ms respectively.

Both the TLE SONOS and the non-TLE SONOS devices display good memory retention properties as Δ Vₜₕ is well maintained up to approximately 10⁴s with negligible observed memory window degradation. The good memory retention is partially due to the relatively thick blocking oxide present in both the TLE SONOS and the non-TLE SONOS devices. Another reason is the lower possibility of stored charges tunneling back to the channel due to the lifted, higher level ground state energy. Advantageously, the TLE SONOS memory cell shows improved operating speeds without compromising on memory retention capability.

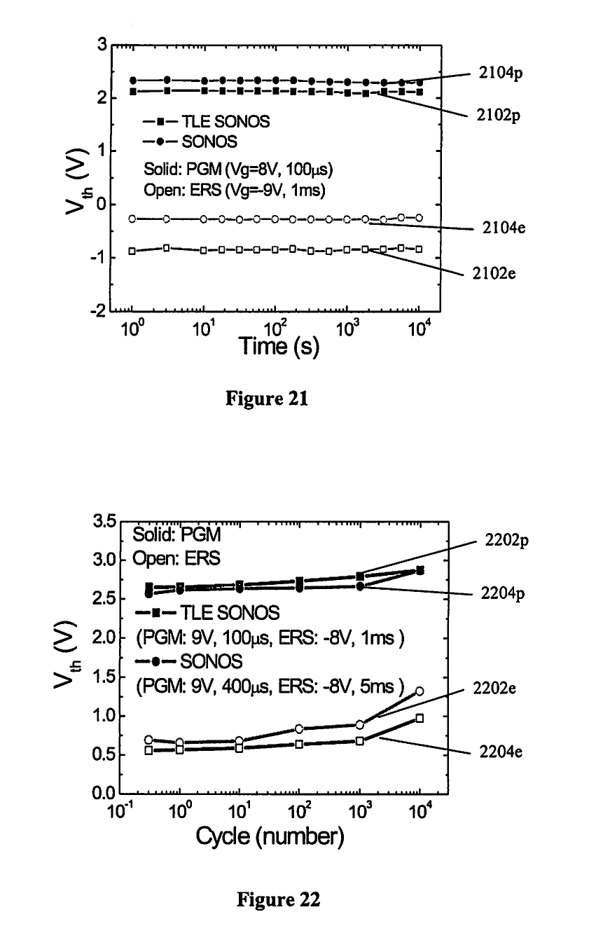

FIG. 22 shows endurance characteristics (through plotting Vth against a number of programming/erasing cycles) of memory cells with a TLE SONOS and a non-TLE SONOS structure, both the memory cells having nanowires of same diameters 5 nm. Graphs 2202p and 2202e refer to the TLE SONOS memory cell, respectively reaching a programmed state (PGM) at 9V for a duration of 100 μs and an erased state (ERS) at −8V for a duration of 1 ms. Graphs 2204p and 2204e refer to the non-TLE SONOS memory reaching a PGM at 9V for a duration of 400 μs and an ERS at −8V for a duration of 5 ms. It is observed, from the cycling results, that the TLE SONOS device has better endurance properties, with smaller Vₜₕ shift, than the non-TLE SONOS device.

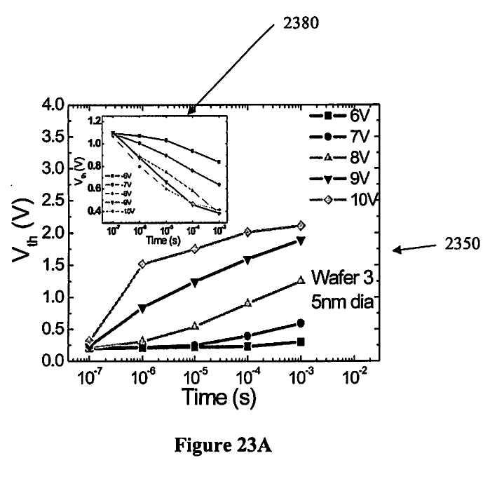

FIG. 23A shows the programming 2350 and erasing 2380 (P/E) characteristics of a memory cell built in accordance with an embodiment of the invention, where the one or more nanocrystals are embedded in the tunneling layer (refer FIGS. 1B and 2B).

For the results shown in FIG. 23A, silicon nanowire having a diameter of around 5 nm and length L_{g} of around 1 μm is used and a SiO₂ layer is used for the tunneling layer. Si NC is used for the one or more first nanocrystals Silicon nitride is used for the charge trapping layer. All P/E were performed using low biasing condition of respectively Vₚ from 6V to 10 V and Vₑ from −6V to −10V applied on the gate region 2308.

The above results discussed with reference to FIGS. 13 to 23 illustrate that a memory cell with a GAA vertically stacked twin nanowire having a TLE SONOS structure achieve faster P/E speed and a wider memory window with negligible trade-off in data retention and endurance properties.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A memory cell comprising:
a first wire shaped channel structure; and
a charge trapping structure surrounding the perimeter surface of the first wire shaped channel structure, the charge trapping structure comprising two charge trapping partial structures, wherein each charge trapping partial structure is formed of a different material capable of storing electrical charges.

2. The memory cell of claim 2, wherein the first wire shaped channel structure is a nanowire.

3. The memory cell of claim 1 or 2, wherein one of the two charge trapping partial structures comprises a first charge trapping layer; and the other of the two charge trapping partial structures comprises one or more first nanocrystals.

4. The memory cell of claims 1 to 3, further comprising:
a second wire shaped channel structure; and
a further charge trapping structure surrounding the perimeter surface of the second wire shaped channel structure, the further charge trapping structure comprising two further charge trapping partial structures, wherein each further charge trapping partial structure is formed of a different material capable of storing electrical charges.

5. The memory cell of claim 4, further comprising:
a gate region surrounding the perimeter surface of the charge trapping structure and the perimeter surface of the further charge trapping structure;
wherein the second wire shaped channel structure is spaced a greater distance from a mounting surface of the gate region than the distance the first wire shaped channel structure is spaced from the mounting surface of the gate region.

6. The memory cell of claim 4 or 5, wherein the first wire shaped channel structure, the second wire shaped channel structure, or both the wire shaped channel structures are nanowires.

7. The memory cell of claims 4 to 6, wherein longitudinal axes of the first wire shaped channel structure and the second wire shaped channel structure are substantially parallel with the mounting surface of the gate region.

8. The memory cell of claims 4 to 7, wherein longitudinal axes of the first channel structure and the second channel structure are substantially perpendicular to an axis normal to the mounting surface of the gate region.

9. The memory cell of claims 4 to 8, wherein one of the two further charge trapping partial structures comprises a second charge trapping layer; and the other of the two further charge trapping partial structures comprises one or more second nanocrystals.

10. The memory cell of any one of the preceding claims, further comprising a first tunneling layer disposed between the perimeter surface of the first wire shaped channel structure and the charge trapping structure.

11. The memory cell of claim 10, wherein the first charge trapping layer surrounds the perimeter surface of the first tunneling layer; and the one or more first nanocrystals surrounds the perimeter surface of the first charge trapping layer.

12. The memory cell of claim 10, wherein the first charge trapping layer surrounds the perimeter surface of the first tunneling layer; and the one or more first nanocrystals are embedded in the first charge trapping layer.

13. The memory cell of claims 4 to 12, further comprising a second tunneling layer disposed between the perimeter surface of the second wire shaped channel structure and the further charge trapping structure.

14. The memory cell of claim 13; wherein the second charge trapping layer surrounds the perimeter surface of the second tunneling layer; and the one or more second nanocrystals surrounds the perimeter surface of the second charge trapping layer.

15. The memory cell of claim 13; wherein the second charge trapping layer surrounds the perimeter surface of the second tunneling layer; and the one or more second nanocrystals are embedded in the second charge trapping layer.

16. The memory cell of claim 11, further comprising a first blocking structure disposed between the first charge trapping layer and the gate region.

17. The memory cell of claims 14, further comprising a second blocking structure between the second charge trapping layer and the gate region.

18. The memory cell of claims 5 to 17, wherein the gate region comprises any one or more of a group of conductive materials of poly-silicon, tantalum nitride, titanium nitride, hafnium nitride, aluminum and tungsten.

19. The memory cell of claims 5 to 18, wherein the gate region is doped with any one or more of a group of n-type dopants consisting of phosphorus, arsenic and antimony.

20. The memory cell of claims 5 to 18, wherein the gate region is doped with any one or more of a group of p-type dopants consisting of boron, aluminum, gallium and indium.

21. The memory cell of claims 4 to 20, wherein the first wire shaped channel structure and the second wire shaped channel structure comprises any one or more of a group consisting of silicon and germanium.

22. The memory cell of claims 10 to 21, wherein the first tunneling layer comprises silicon dioxide (SiO₂).

23. The memory cell of claims 3 to 22, wherein the first charge trapping layer comprises any one or more of a group of high dielectric materials of silicon nitride (Si₃N₄), hafnium dioxide (HfO₂) and aluminum oxide (Al₂O₃); and the one or more first nanocrystals comprises any one or more of a group of metals of silicon nanocrystals (Si—NC), germanium nanocrystals and tungsten nanocrystals.

24. The memory cell of claims 16 to 24, wherein the first blocking structure comprises SiO₂.

25. The memory cell of claims 13 to 24, wherein the second tunneling layer comprises SiO₂.

26. The memory cell of claims 9 to 25, wherein the second charge trapping layer comprises any one or more of a group of high dielectric materials of Si₃N₄, hafnium dioxide (HfO₂) and aluminum oxide (Al₂O₃); and the one or more second nanocrystals comprises any one or more of a group of metals of Si—NC, germanium nanocrystals and tungsten nanocrystals.

27. The memory cell of claims 17 to 26, wherein the second blocking structure comprises SiO₂.

28. A method of forming a memory cell comprising the steps of
forming a first wire shaped channel structure; and
forming a charge trapping structure surrounding the perimeter surface of the first wire shaped channel structure, the charge trapping structure comprising two charge trapping partial structures, wherein each charge trapping partial structure is formed of a different material capable of storing electrical charges.

29. A method of forming a memory cell, the method comprising the steps of:
forming from a single conducting layer a first wire shaped channel structure and a second wire shaped channel structure; and
forming a gate region around the perimeter surface of the first wire shaped channel structure and the perimeter surface of the second wire shaped channel structure;
wherein the second wire shaped channel structure is spaced a greater distance from a mounting surface of the gate region than the distance the first wire shaped channel structure is spaced from the mounting surface of the gate region.

30. The method of claim 29, wherein forming from the single conducting layer the first wire shaped channel structure and the second wire shaped channel structure further comprises the steps of
forming a fin structure from the single conducting layer;
oxidizing a fin portion of the fin structure; and
removing the oxidized portion of the fin portion to release the first wire shaped channel structure and the wire shaped second channel structure.

31. The method of claim 30, wherein the step of forming the fin structure from the single conducting layer is performed using a phase shift mask lithography process.

32. The method of claim 30 or 31, wherein the step of removing the oxidized portion of the fin portion comprises dissolving the oxidized portion of the fin portion in a solution of diluted hydrofluoric acid.

33. The method of claims 29 to 32, wherein the first wire shaped channel structure, the second wire shaped channel structure, or both the wire shaped channel structures are nanowires.

34. The method of claims 29 to 33, further comprising the step of
forming a first tunneling layer surrounding the perimeter surface of the first wire shaped channel structure.

35. The method of claim 34, further comprising the step of forming a charge trapping structure surrounding the perimeter surface of the first tunneling layer, the charge trapping structure comprising two charge trapping partial structures, wherein each charge trapping partial structure is formed of a different material capable of storing electrical charges.

36. The method of claim 35, wherein one of the two charge trapping partial structures comprises a first charge trapping layer; and the other of the two charge trapping partial structures comprises one or more first nanocrystals.

37. The method of claim 36, further comprising the steps of forming the first charge trapping layer surrounding the perimeter surface of the first tunneling layer; and
forming the one or more first nanocrystals surrounding the perimeter surface of the first charge trapping layer.

38. The method of claim 36, further comprising the steps of
forming the first charge trapping layer surrounding the perimeter surface of the first tunneling layer; and
forming the one or more first nanocrystals in the first charge trapping layer.

39. The method of claims 29 to 38, wherein the step of forming the gate region further comprises the step of forming a second tunneling layer surrounding the perimeter surface of the second wire shaped channel structure.

40. The method of claim 34, further comprising the step of forming a further charge trapping structure surrounding the perimeter surface of the second tunneling layer, the further charge trapping structure comprising two further charge trapping partial structures, wherein each further charge trapping partial structure is formed of a different material capable of storing electrical charges.

41. The method of claim 40, wherein one of the two further charge trapping partial structures comprises a second charge trapping layer; and the other of the two further charge trapping partial structures comprises one or more second nanocrystals.

42. The method of claim 41; further comprising the steps of
forming the second charge trapping layer surrounding the perimeter surface of the second tunneling layer; and
forming the one or more second nanocrystals surrounding the second charge trapping layer.

43. The method of claim 41; further comprising the steps of
forming the second charge trapping layer surrounding the perimeter surface of the second tunneling layer; and
forming the one or more second nanocrystals in the second charge trapping layer.

44. The method of claim 37, further comprising the step of forming a first blocking structure between the first charge trapping layer and the gate region.

45. The method of claims 42, further comprising the step of forming a second blocking structure between the second charge trapping layer and the gate region.

46. The method of claims 29 to 45, wherein the gate region comprises any one or more of a group of conductive materials of poly-silicon, tantalum nitride, titanium nitride, hafnium nitride, aluminum and tungsten.

47. The method of claims 29 to 46, further comprising the step of doping the gate region with any one or more of a group of n-type dopants consisting of phosphorus, arsenic and antimony.

48. The method of claims 29 to 46, further comprising the step of doping the gate electrode with any one or more of a group of p-type dopants consisting of boron, aluminum, gallium and indium.

49. The method of claims 29 to 48, wherein the first wire shaped channel and the second wire shaped channel structure comprises any one or more of a group consisting of silicon and germanium.

50. The method of claims 34 to 49, wherein the first tunneling layer comprises SiO₂.

51. The method of claims 36 to 51, wherein the first charge trapping layer comprises any one or more of a group of high dielectric materials of Si₃N₄, hafnium dioxide (HfO₂) and aluminum oxide (Al₂O₃); and the one or more first nanocrystals comprises any one or more of a group of metals of Si—NC, germanium nanocrystals and tungsten nanocrystals.

52. The method of claims 44 to 52, wherein the first blocking structure comprises SiO₂.

53. The method of claims 39 to 52, wherein the second tunneling layer comprises SiO₂.

54. The method of claims 41 to 53, wherein the second charge trapping layer comprises any one or more of a group of high dielectric material of Si₃N₄, hafnium dioxide (HfO₂) and aluminum oxide (Al₂O₃); and the one or more second nanocrystals comprises any one or more of a group of metals of Si—NC, germanium nanocrystals and tungsten nanocrystals.

55. The memory cell of claims 45 to 54, wherein the second blocking structure comprises SiO₂.
